(19) United States
(12) Patent Application Publication
(10) Pub. No.: US 2014/0049261 A1
(43) Pub. Date: Feb. 20, 2014

(54) PULSED MISSING GROUND DETECTOR CIRCUIT

(71) Applicant: Albert Flack, Lake Arrowhead, CA (US)

(72) Inventor: Albert Flack, Lake Arrowhead, CA (US)

(73) Assignee: AeroVironment, Inc., Monrovia (CA)

(21) Appl. No.: 14/114,497

(22) PCT Filed: Apr. 30, 2012
(86) PCT No.: PCT/US12/35875

§ 371 Date: Oct. 28, 2013

Related U.S. Application Data
(60) Provisional application No. 61/480,367, filed on Apr. 28, 2011.

(51) Int. Cl. G01R 31/02

(52) U.S. Cl. CPC G01R 31/025
USPC 324/509

(57) ABSTRACT

In one implementation, a method is provided to detect a ground fault. This includes applying a pulsed test impedance and detecting a utility power voltage with and without the pulsed test impedance applied. It further includes detecting a test current through the pulsed test impedance to ground and determining whether a ground fault exists based on the detected test current and the detected utility power voltage with and without the pulsed test impedance applied.

### CROSS REFERENCE TO RELATED APPLICATIONS

The present application claims the benefit of U.S. Provisional Application No. 61/480,367, filed Apr. 28, 2011, by Albert Flack, entitled PULSED MISSING GROUND DETECTOR CIRCUIT, herein incorporated by reference in its entirety.

The present application is related to PCT Application No. PCT/US11/32576, filed Apr. 14, 2011, by Flack, entitled GROUND FAULT INTERRUPT CIRCUIT FOR ELECTRIC VEHICLE, herein incorporated by reference in its entirety.

The present application is related PCT Application No. PCT/US11/48298, filed Aug. 18, 2011, by Flack, entitled GROUND FAULT INTERRUPT AUTOMATIC TEST METHOD FOR ELECTRIC VEHICLE, which claims the priority of U.S. Provisional Application 61/374,612 filed Aug. 18, 2010, by Flack, entitled GROUND FAULT INTERRUPT AUTOMATIC TEST METHOD FOR ELECTRIC VEHICLE, both herein incorporated by reference in their entireties.

### BACKGROUND

One way to charge an electric vehicle is to supply the vehicle with power so that a charger in the vehicle can charge the battery in the vehicle. A missing ground in the electrical system of the car is a shock hazard if a person comes in contact with the vehicle.

It is possible to apply a test impedance from the AC line to the sense ground point in a circuit to determine if the utility ground line has a proper connected impedance to earth. In order for this signal to be accurately determined, the test impedance should be as low as is practical. A low test impedance, however, creates unwanted power losses and common mode currents that can cause upstream GFI trips.

What is needed is a way to test for the existence of a missing ground without creating unwanted GFI trips.

### SUMMARY

In one implementation, a method is provided for to detect a ground fault. This includes applying a pulsed test impedance and detecting a utility power voltage with and without the pulsed test impedance applied. The method further includes detecting a test current through the pulsed test impedance to ground and determining whether a ground fault exists based on the detected test current and the detected utility power voltage with and without the pulsed test impedance applied.

In one embodiment, a ground fault detection circuit is provided. The circuit includes a line voltage sense circuit connected to a utility power input and a pulse control transistor connected via a current generating resistor to a utility power input. The circuit further includes a current sense circuit comprising a current sense resistor connected to the utility power via the pulse control transistor.

In one embodiment, the pulsed test impedance is pulsed with a limited duration and frequency so that a ground fault interrupt circuit does not indicate a short circuit to ground. In some embodiments, the pulsed test impedance may be a single pulse.

In one embodiment, an electric vehicle supply equipment system is provided, which includes a utility power input and a ground fault detection circuit. The ground fault detection circuit is connected to the utility power input and includes a line voltage sense circuit connected to the utility power input. The ground fault detection circuit further includes a pulse control transistor connected via a current generating resistor to a utility power input and a current sense circuit comprising a current sense resistor connected to the utility power via the pulse control transistor. The system further includes processor adapted determine a ground impedance based on outputs from the line voltage sense circuit and the current sense circuit in response to a pulsed connection and disconnection of the current sense resistor by the pulse control transistor.

### BRIEF DESCRIPTION OF THE DRAWINGS

The features and advantages of the present invention will be better understood with regard to the following description, appended claims, and accompanying drawings where:

FIG. 1 shows a simplified schematic of a single phase pulsed impedance circuit in accordance with one embodiment.

FIG. 2 is a plot illustrating example waveforms from the single phase pulsed impedance circuit of FIG. 1.

FIG. 3 is a plot illustrating example waveforms from the single phase pulsed impedance circuit of FIG. 1.

FIG. 4 is a plot illustrating an example waveform from the single phase pulsed impedance circuit of FIG. 1.

FIG. 5 is a plot illustrating an example waveform from the single phase pulsed impedance circuit of FIG. 1.

FIG. 6 is a plot illustrating an example waveform from the single phase pulsed impedance circuit of FIG. 1.

FIG. 7 is a plot illustrating an example waveform from the single phase pulsed impedance circuit of FIG. 1.

FIG. 8 is a plot illustrating an example waveform from the single phase pulsed impedance circuit of FIG. 1.

FIG. 9 is a plot illustrating an example waveform from the single phase pulsed impedance circuit of FIG. 1.

FIG. 10 is a plot illustrating an example waveform from the single phase pulsed impedance circuit of FIG. 1.

FIG. 11 shows a simplified schematic of a single phase pulsed impedance circuit in accordance with one embodiment.

FIG. 12 shows a plot illustrating an example waveform from the single phase pulsed impedance circuit of FIG. 11.

FIG. 12 shows a plot illustrating an example waveform from the single phase pulsed impedance circuit of FIG. 11.

FIG. 13 shows a simplified schematic of a dual phase pulsed impedance circuit in accordance with one embodiment.

FIG. 14 shows a plot illustrating an example waveform from the dual phase pulsed impedance circuit of FIG. 13.

FIGS. 15A and 15B show plots illustrating an example waveform from the dual phase pulsed impedance circuit of FIG. 13.

FIGS. 16A and 16B are show plots illustrating an example waveform from the dual phase pulsed impedance circuit of FIG. 13.

FIG. 17 is shows a simplified schematic of a single phase pulsed impedance circuit in accordance with one embodiment.

FIG. 18 is a simplified schematic view of utility power supply equipment.

FIG. 19 is a partial schematic showing of a processor associated with the utility power supply equipment.

### DESCRIPTION

In accordance with various implementations, one way to determine if the utility ground line has a properly connected impedance to earth, while at the same time circumventing some of the unwanted power losses and common mode currents that can cause GFI trips, is to pulse the test impedance so that it is not a continuous function. This can significantly reduce the effective RMS common mode current and associated power losses. This also allows use of a lower impedance than would otherwise be possible for the impedance test, resulting in a better determination of lower ground resistance faults.

The determination of the ground connection is made by reading the offset of voltage when the test impedance is applied. The amplitude of the offset measured before, during and after the application of the test impedance will indicate the value of the ground wire to earth connection. The ability to resolve lower ground resistances is improved by reducing the test impedance or increasing the signal gain. The typical analog to digital converter in the CPU has about 3 mV of bit conversion resolution. The actual useful resolution is closer to 10 mV with device errors taken into account.

Increased common mode current during the test may not contribute greatly to an upstream GFI trip issue if it is limited in duration or applied at a frequency lower than the GFI trip circuit is designed for.

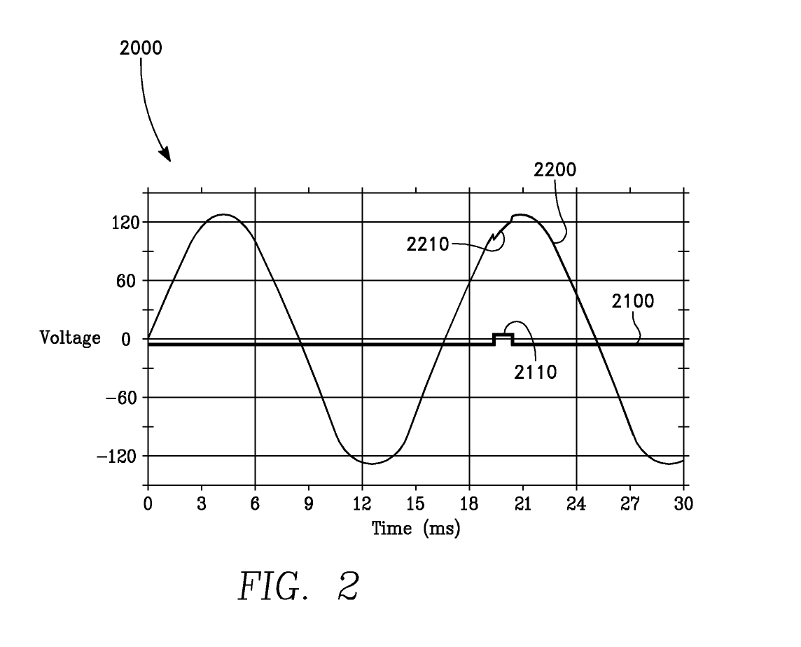

Shown in FIGS. 2-10, 12, 14, and 15 is data from various GFI device testing at different RMS waveforms and frequencies in accordance with some implementations of this approach. In accordance with various implementations, the test pulse application can be made somewhat random, but should occur where the voltage amplitude is high for best results. The higher section of the waveform can be offset and amplified for greater sensitivity.

The AC voltage conversion process that the CPU performs could be made every other line cycle without causing any system problems. The other cycle could be used for missing ground detection. The decision to shutdown due to missing ground could be made after many samples are made. In one implementation, thirty samples over two seconds would suffice for a fault determination.

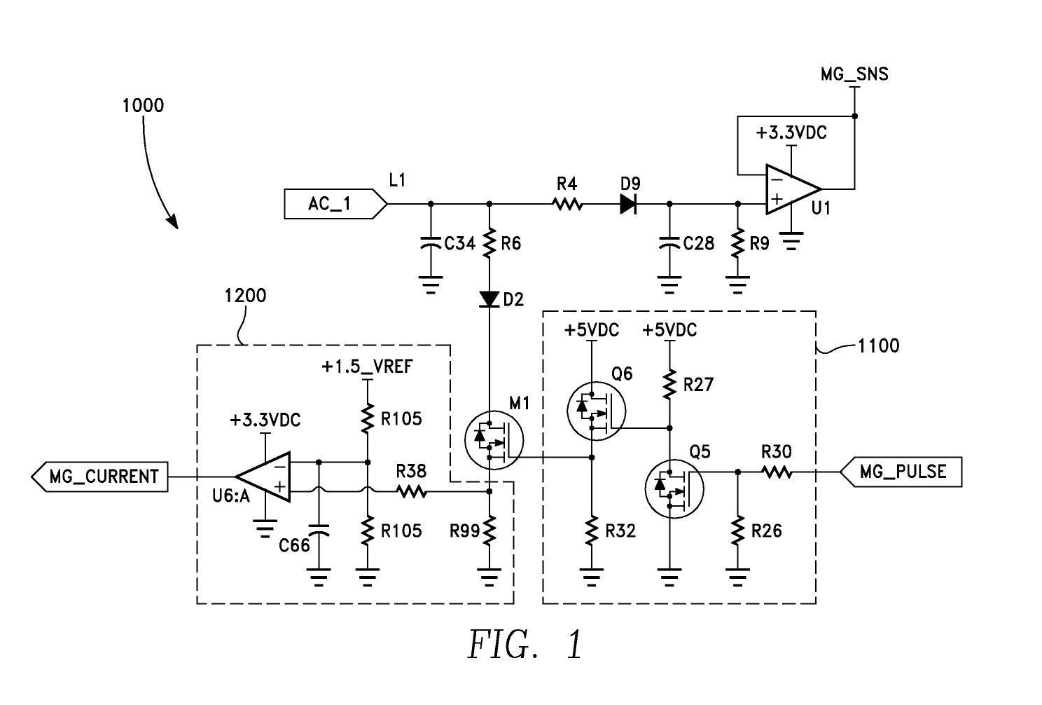

FIG. 1 shows a simplified schematic of a single phase pulsed impedance circuit 1000 in accordance with one embodiment. In the pulsed impedance circuit 1000 the test impedance can be much higher than in a conventional constant application method. In some embodiments, this circuit 1000 can determine a ground impedance of 2K ohms using a test impedance of 50K ohms, for example.

In the circuit 1000 of FIG. 1, a pulse control transistor M1 is connected via diode D2 to a high power current generating resistor R6, such as 15 Kohms. R6 is the applied test impedance. The pulse control transistor M1 is controlled by an optional gate driver circuit 1100. The gate driver circuit 1100 is supplied with a logic level signal MG_PULSE for processing such as to a system microprocessor (not shown). The gate drive circuit 1100 provides a higher voltage to drive the gate control transistor.

The current sense circuit 1200 provides a logic level output MG_CURRENT for processing based on the sensed current through current sense resistor R99, which is a low resistance resistor, such as 60 ohms. This sense resistor 99 and associated monitor U6 provides a failsafe “self test” capability in that, if the circuit were to fail to apply the test impedance to the utility lines, the absence of the test current induced voltage across R99 would provide an indication that the circuit has failed and therefore represents a secondary fault determination that makes the overall circuit failsafe. A constant indication of current on this sense resistor R99 also provides a fault condition of the test pulse being constantly applied. This is another assumed failure of the circuit and is cause to indicate a fault condition.

The sense amplifier U1 senses the line voltage and outputs analog sense signal MG_SNS.

FIG. 2 is a plot illustrating example waveforms from the single phase pulsed impedance circuit 1000 of FIG. 1. In this example, the current generating resistor(s) impedance R6 is 50 k, and the ground resistance at the utility power source is 2 K ohms.

Waveform 2200 shows the AC line voltage L1, indicated as signal AC_1 in FIG. 1, with respect to the sense ground. Waveform 2100 shows the pulse gate of the test Mosfet. The first cycle is what the signal would look like during the test if the ground impedance was very low. The second cycle of the AC waveform 2200 displays a characteristic offset voltage at 2210 reading during the gate pulse MG_PULSE period 2110, due to the 50 K ohms current generating resistance R6, when the L1 ground resistance is 2K ohms.

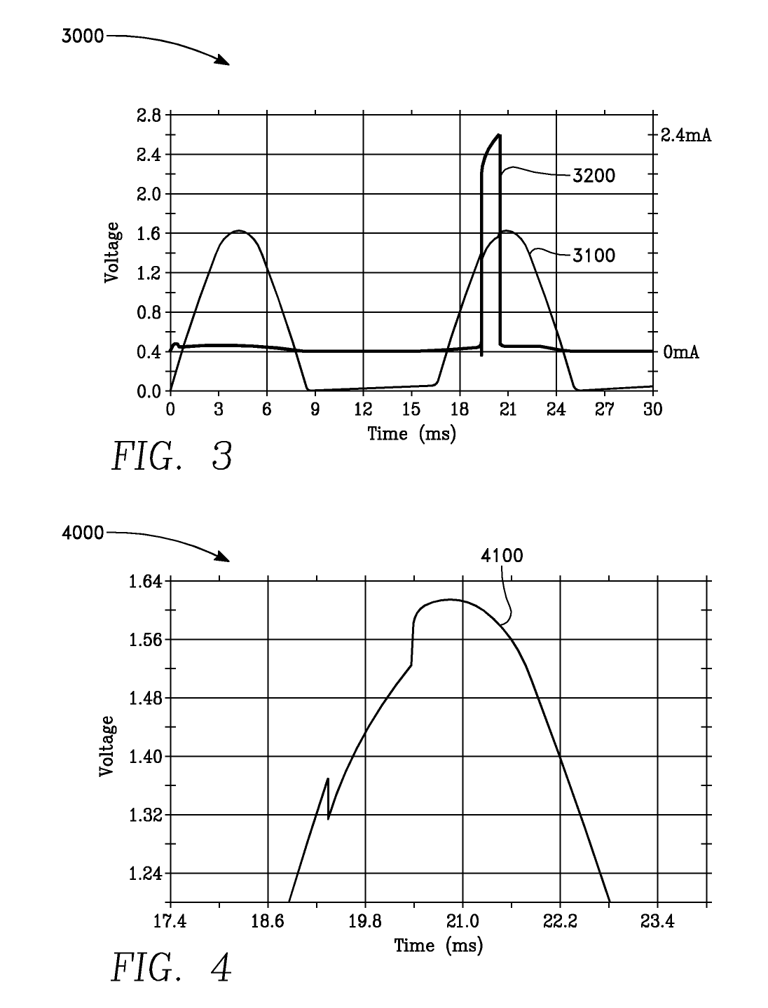

FIG. 3 is a plot 3000 illustrating example waveforms from the single phase pulsed impedance circuit 1000 of FIG. 1. In this example, the current generating resistor(s) impedance R6 is 50 k, and the ground line resistance at the utility power source is 2 K ohms.

Waveform 3100 shows the scaled circuit utility voltage with respect to the sense ground. Waveform 3200 shows the common mode current 3200 that is generated by the impedance application. This current has a peak value shown of 2.4 mA but for only 1 mS and the RMS value is only about 0.15 mA. This should not trip an upstream GFI that is looking for an extended current signal. Longer or shorter pulse widths can be used as the external conditions allow.

FIG. 4 is a plot 4000 illustrating an example waveform from the single phase pulsed impedance circuit 1000 of FIG. 1. In FIG. 4, the current generating resistor(s) impedance R6 is 50 k, and the ground resistance at the utility power source is 2 K ohms. Waveform 4100 shows the detailed scaled circuit utility voltage with respect to the sense ground. This signal can be distinguished from noise or other wave irregularities when the gate signal is used as a sync indicator. Moving the pulse to various locations within the AC wave form will further help to identify it as the correct signal.

FIG. 5 is a plot 5000 illustrating an example waveform from the single phase pulsed impedance circuit 1000 of FIG. 1. In FIG. 5, waveform 5100 shows the detailed scaled circuit utility voltage with respect to the sense ground. This signal 5100 shows the use of repetitive pulses of the MG_PULSE signal, which proves characteristic offset voltage 5110, 5112, and 5114, to help further identify the proper signal. This also reduces RMS current and increases current frequency.

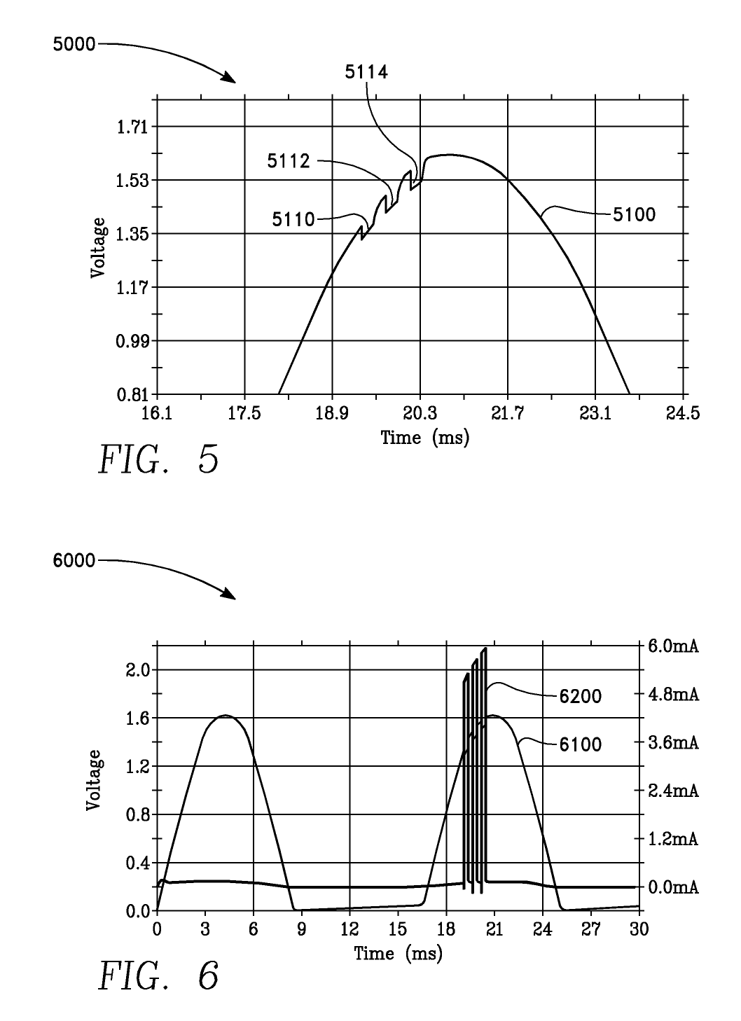

FIG. 6 is a plot 6000 illustrating an example waveform from the single phase pulsed impedance circuit 1000 of FIG. 1 with a 20 K ohm current generating resistor R6 and a 1 K ohm the ground line resistance at the utility power source.

Waveform 6100 shows the scaled circuit utility voltage with respect to the sense ground. Waveform 6200 shows the common mode current that is generated by the application of a higher impedance at R6. This current has a peak value shown of about 6 mA but for only 1 mS and the RMS value is only 0.2 mA. This should not trip an upstream GFI that is looking for an extended current signal.

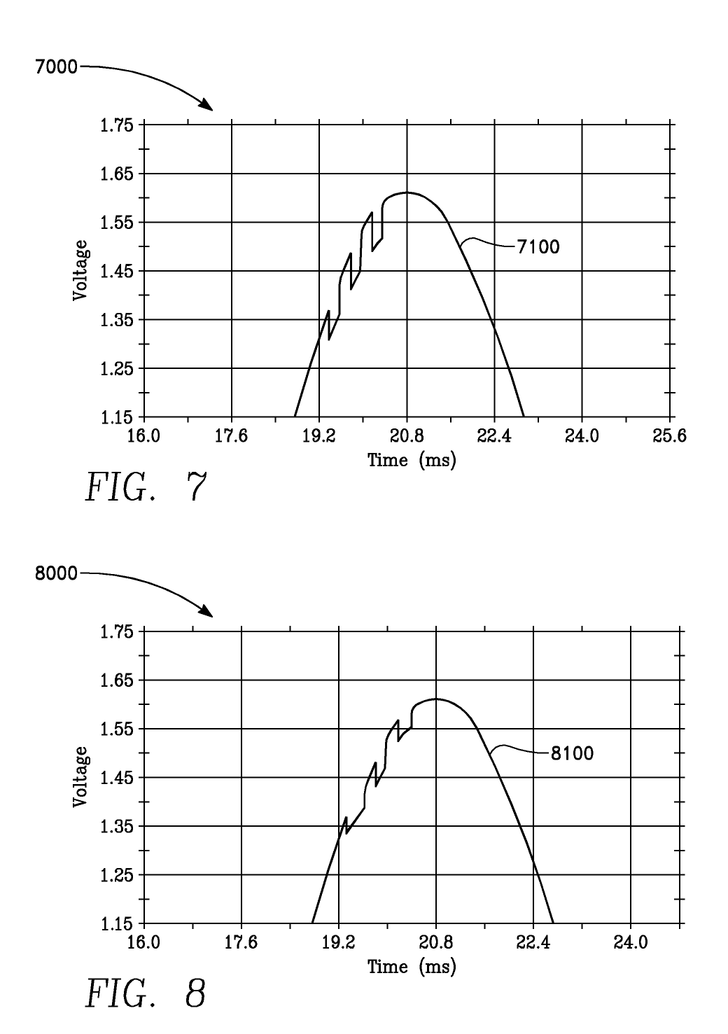

FIG. 7 is a plot 7000 illustrating an example waveform from the single phase pulsed impedance circuit 1000 of FIG. 1, with a 20 K ohm current generating resistor R6 and a 1 K ohm the ground line resistance at the utility power source. Waveform 7100 shows the scaled circuit utility voltage with respect to the sense ground. This shows the detailed signal amplitude with a 1 K ohm ground impedance.

FIG. 8 is a plot 8000 illustrating an example waveform from the single phase pulsed impedance circuit 1000 of FIG. 1 with a 20 K ohm current generating resistor R6 and a 500 ohm the ground line resistance at the utility power source. Waveform 8100 shows the scaled circuit utility voltage with respect to the sense ground. This shows the detailed signal amplitude with a 500 ohm ground impedance.

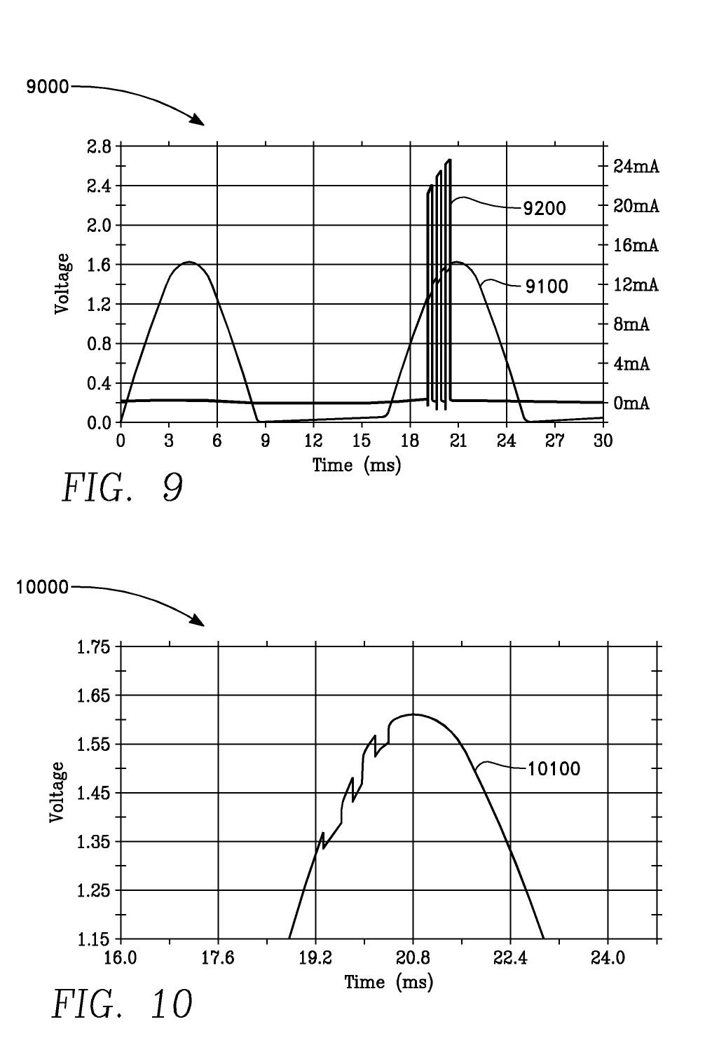

FIG. 9 is a plot 9000 illustrating an example waveform from the single phase pulsed impedance circuit 1000 of FIG. 1 with a 5 K ohm current generating resistor R6 and a 100 ohm the ground line resistance at the utility power source. Waveform 8100 shows the scaled circuit utility voltage with respect to the sense ground. Waveform 9200 shows the common mode current that is generated by the higher impedance application. This current has a peak value shown of 24 mA but for only 1 mS and the RMS value is only 1.4 mA. This may not trip an upstream GFI that is looking for an extended current signal. This shows the ability of the circuit to determine low ground resistance.

FIG. 10 is a plot 10000 illustrating an example waveform from the single phase pulsed impedance circuit 1000 of FIG. 1 with a 5 K ohm current generating resistor R6 and a 100 ohm the ground line resistance at the utility power source. Waveform 10100 shows the scaled circuit utility voltage with respect to the sense ground. This shows the detailed signal amplitude with a 100 ohm ground impedance.

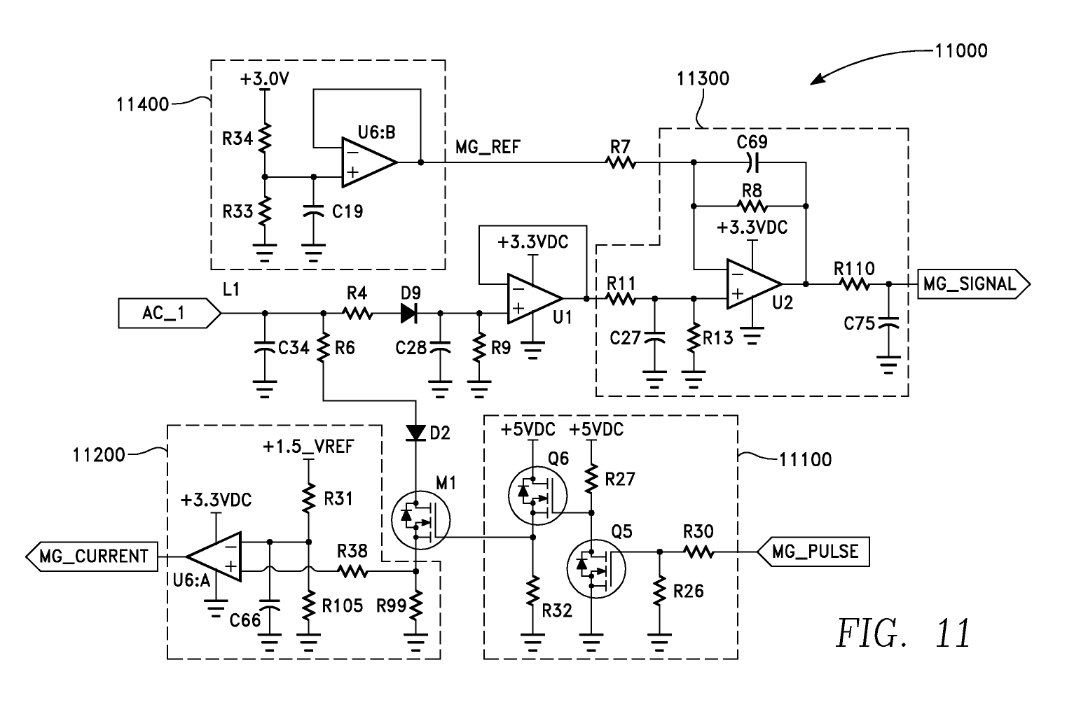

FIG. 11 shows a simplified schematic 11000 of a single phase pulsed impedance circuit in accordance with one embodiment. This embodiment, further has an extended amplification gain stage 11300 and a reference voltage generator 11400 to provide the analog level signal MG_SIGNAL, which may be sent to the system processor (not shown).

As with FIG. 1 above, in the pulsed impedance circuit 11000 the test impedance can be much lower than in a conventional constant application method. In some embodiments, this circuit 1000 can determine a ground impedance of 2K ohms using a test impedance of 50K ohms, for example.

In the circuit 11000 the pulse control transistor M1 is connected via diode D2 to a high power current generating resistor R6, such as 15 Kohms. R6 is the applied test impedance. The pulse control transistor M1 is controlled by an optional gate driver circuit 11100. The gate driver circuit 11100 is supplied with a logic level signal MG_PULSE for processing, such as to a system microprocessor (not show). The gate drive circuit 11100 provides a higher voltage to drive the gate control transistor M1.

The current sense circuit 11200 has provides a logic level output MG_CURRENT for processing based on the sensed current through current sense resistor R99, which is a low resistance resistor, such as 60 ohms.

The sense amplifier U1 senses the line voltage and outputs an analog sense signal MG_SNS.

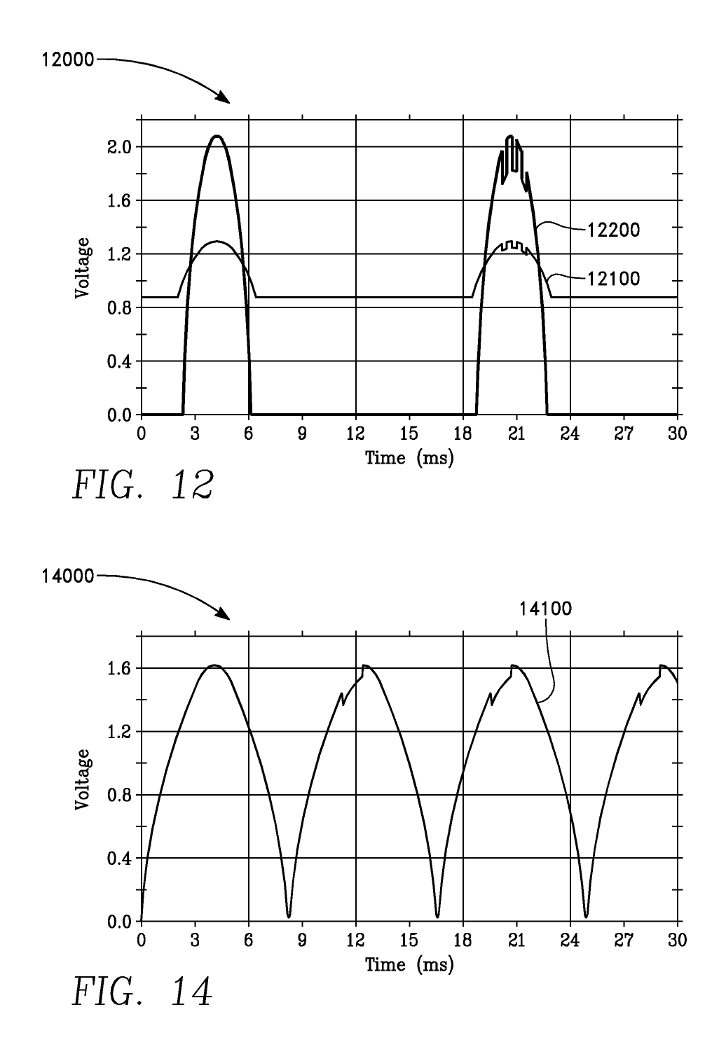

FIG. 12 shows a plot 11200 illustrating an example waveform from the single phase pulsed impedance circuit 11000 of FIG. 11 with a 50 K ohm current generating resistor R6 and a 2000 ohm the ground line resistance at the utility power source. Waveform 12100 shows the scaled circuit utility voltage with respect to the sense ground. The waveform 12200 shows the signal but amplified just above the 1.1 volt level for more signal value.

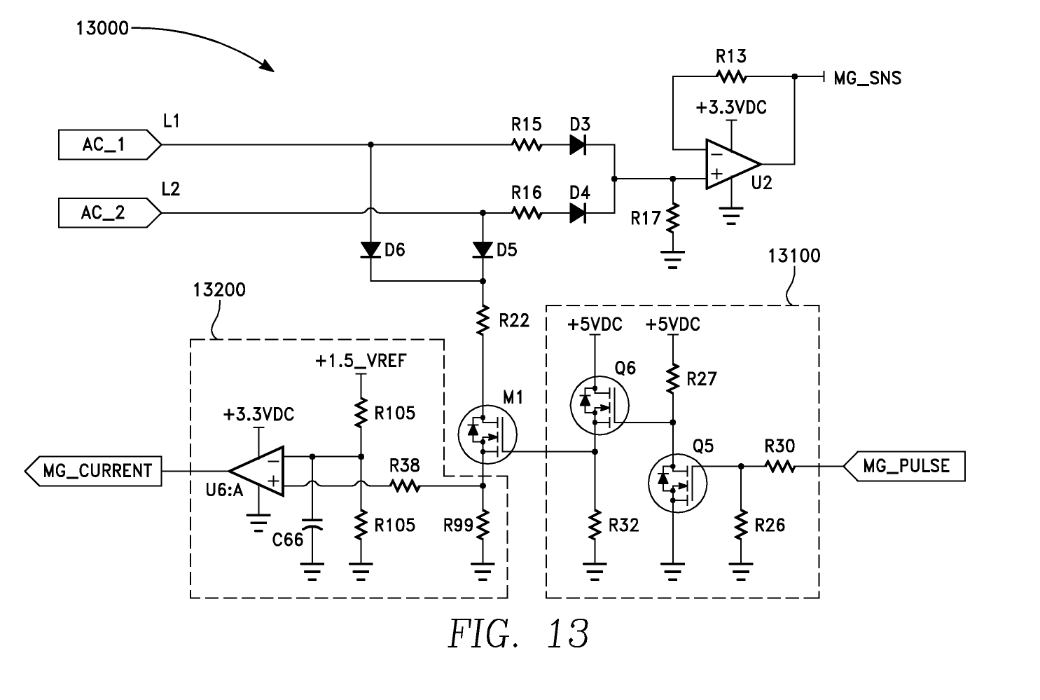

FIG. 13 shows a simplified schematic of a dual phase L1 and L2 pulsed impedance circuit 13000 in accordance with one embodiment. This circuit 13000 is a dual version of the circuit 1000 of FIG. 1 one. It allows for the faster pulse availability. It also allows for missing ground determination if one phase drops out.

FIG. 14 shows a plot 14000 illustrating an example waveform from the dual phase pulsed impedance circuit 13000 of FIG. 13 with a 50 K ohm current generating resistor R22 and a 2 K ohm the ground line resistance at the utility power source.

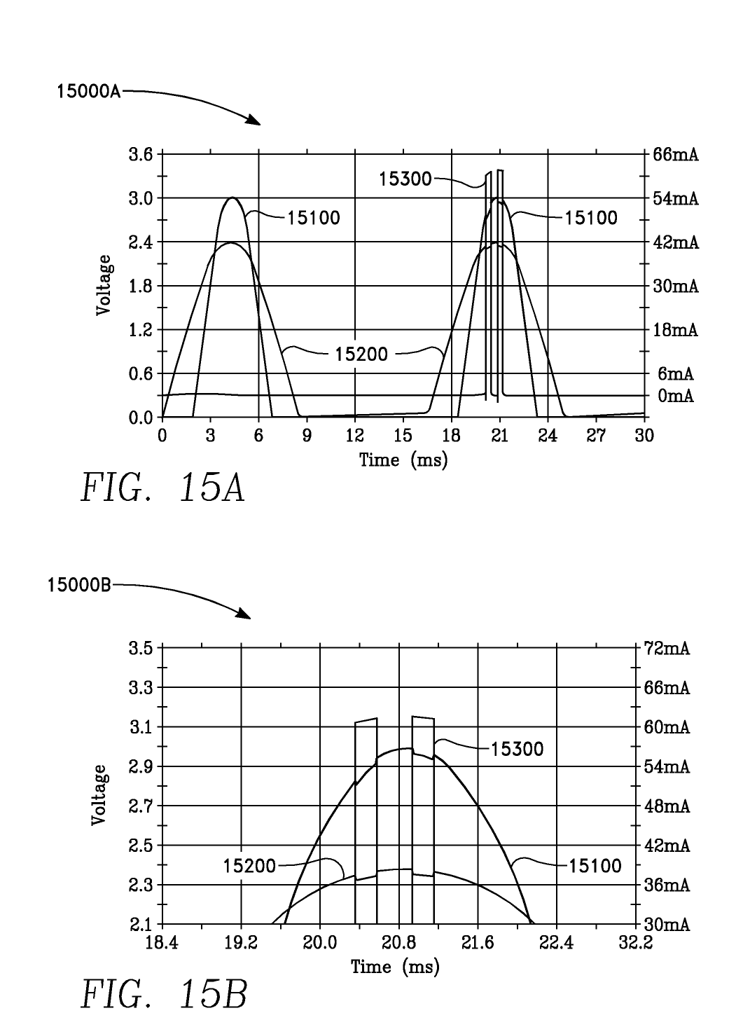

FIGS. 15A and 15B show plots 15000 illustrating an example waveform from the dual phase pulsed impedance circuit 13000 of FIG. 13 with a 3 K ohm current generating resistor R22 and a 25 ohm the ground line resistance at the utility power source. This example shows a waveforms reacting to a 25 ohm ground resistance. Waveform 15100A shows the scaled circuit utility voltage with respect to the sense ground. The waveform 15100B shows the signal but amplified just above the 1.5 volt level for more signal value. The waveform 15100C shows the current during the test pulses. This example uses two test pulses to reduce the RMS current that an upstream GFI might see. The current max is 60 mA but the RMS for one pulse is 0.7 mA, so for two 1.4 mA. FIG. 15B is an expanded time scale of the waveforms 15100A, 15200A, and 15300A. This shows greater circuit capability to determine small ground impedances.

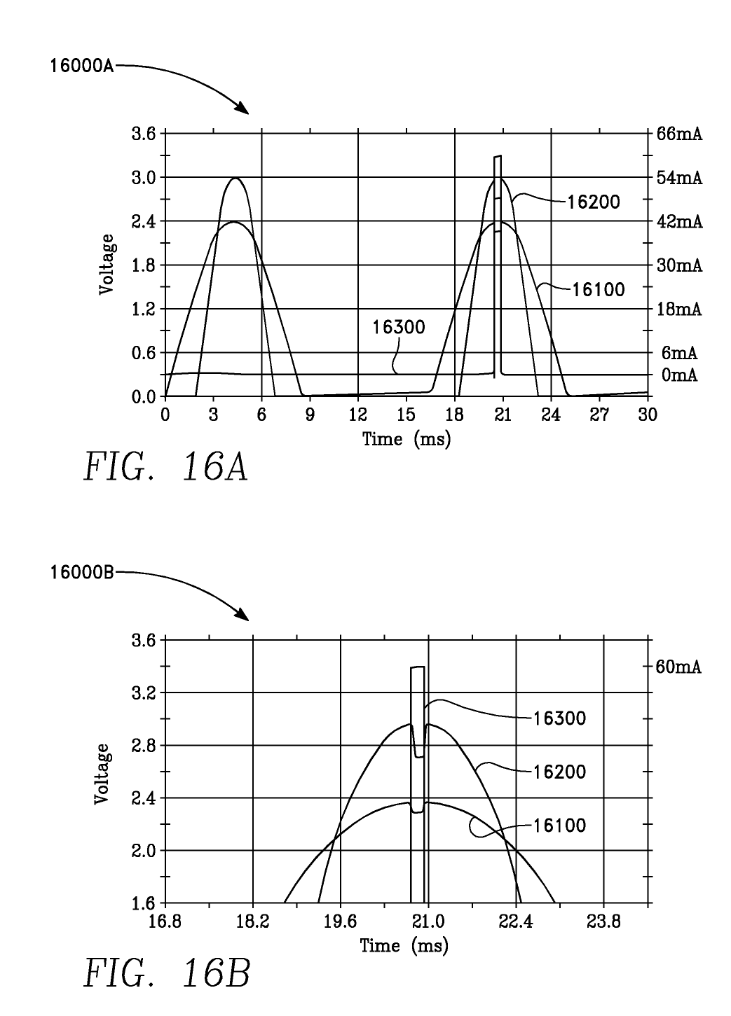

FIGS. 16A and 16B are show plots 16000 illustrating an example waveform from the dual phase pulsed impedance circuit 13000 of FIG. 13 with a 3 K ohm current generating resistor R22 and a 100 ohm the ground line resistance at the utility power source. This example shows a method of reacting to a 100 ohm ground resistance. Waveform 16100 shows the scaled circuit utility voltage with respect to the sense ground. Waveform 16200 shows the signal but amplified just above the 1.5 volt level for more signal value. Waveform 16300 shows the current during the test pulses. This example uses one test pulses to reduce the RMS current that an upstream GFI might see. The current max is 60 mA but the RMS for one pulse is 0.7 mA.

In an example test procedure in accordance with various implementations:
1. Wait for the desired point in the waveform. This will be where the line voltage is high enough to provide the needed current.
2. Read the line test voltage (V1) at least 3 times in rapid succession to obtain an average.
3. Immediately apply the test signal (Mosfet on).
4. Read the line test voltage (V2) at least 3 times in rapid succession to obtain an average.
5. Turn off the test signal (Mosfet off).
6. Read the line test voltage (V3) at least 3 times in rapid succession to obtain an average.
7. Use the voltages and the current values to calculate the series impedance.
8. If greater than the limit, shutdown the system.

It is not necessary in all implementations to take measurements both before and after applying the pulsed impedance signal. Further, it is not necessary in all implementations to take at least 3 reading of the line test voltages. For example, another test sequence is as follows:
1. The line voltage at the desired test application point in the AC cycle is measured without the test pulse being applied.
2. The next line voltage cycle is then read with the test pulse applied which generates the voltage deviation.
3. The difference between these two voltages represents the impedance effect of the applied current.

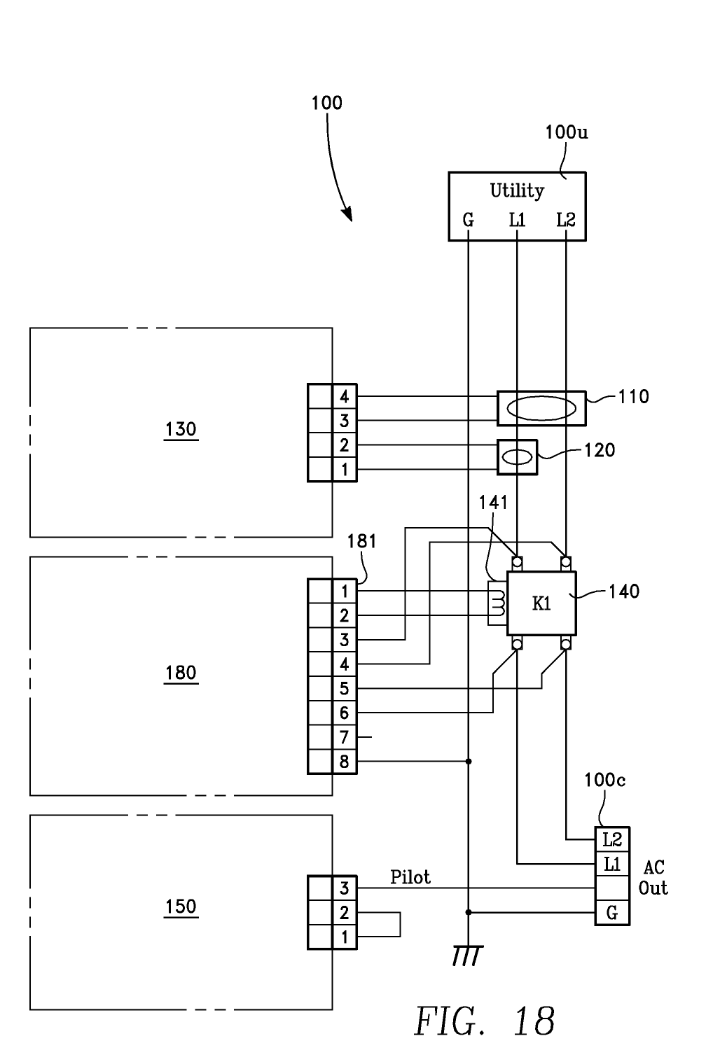

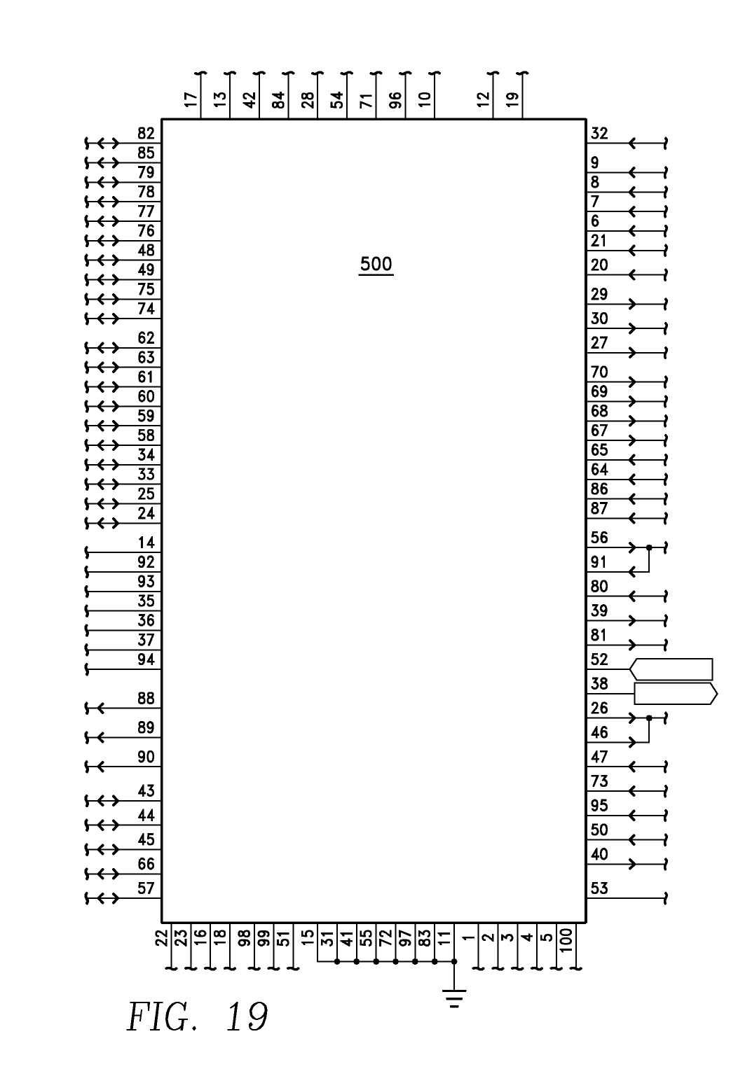

The impedance of the ground connection to earth is determined by dividing the utility line voltage drop by the current drop. If there is one or more gain stages, for example gain stage 11300 in FIG. 11, the gain must be divided out when determining the actual voltage. Further, the effect of any resistive voltage divider networks along the path of the voltage sense amplifier, for example R4 and R9 in FIG. 11, must be taken into account when determining the actual drop of the line voltage. Thus, any voltage divider ratio should be compensated by multiplying by the reciprocal when determining the actual drop of the line voltage. The impedance of the ground connection can be determined with a system processor 500 (shown in FIG. 19) associated with the electric supply equipment (shown in FIG. 18).

One advantage of various embodiments is that the full circuit is low cost using, mostly resistors.

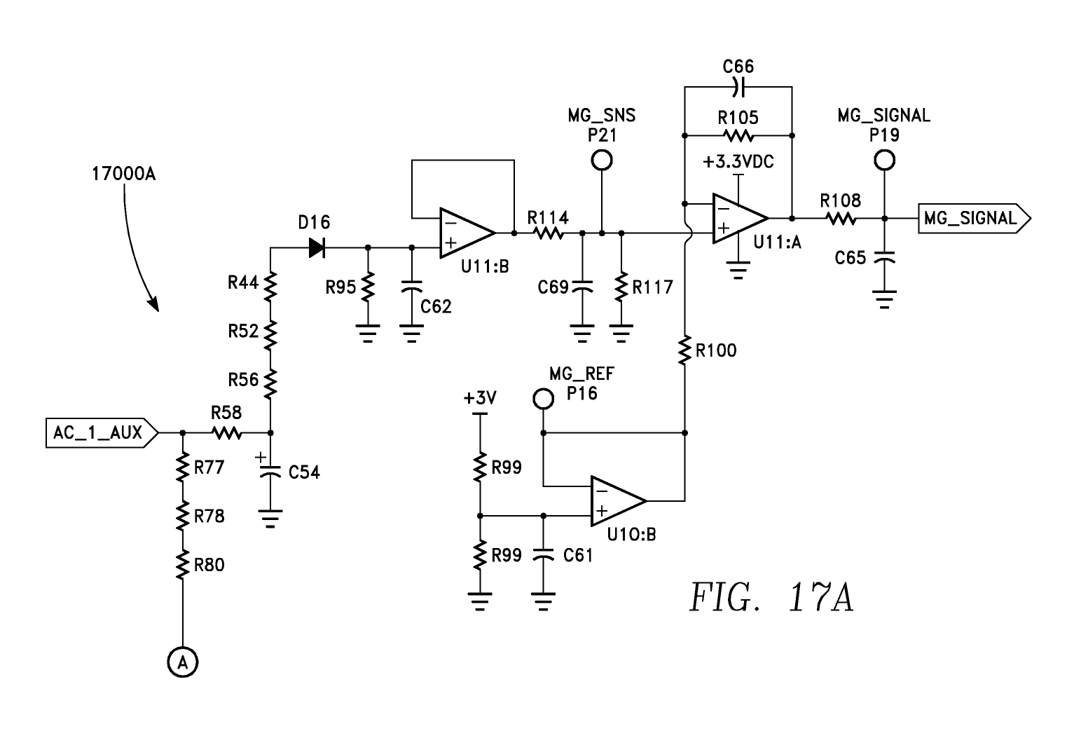

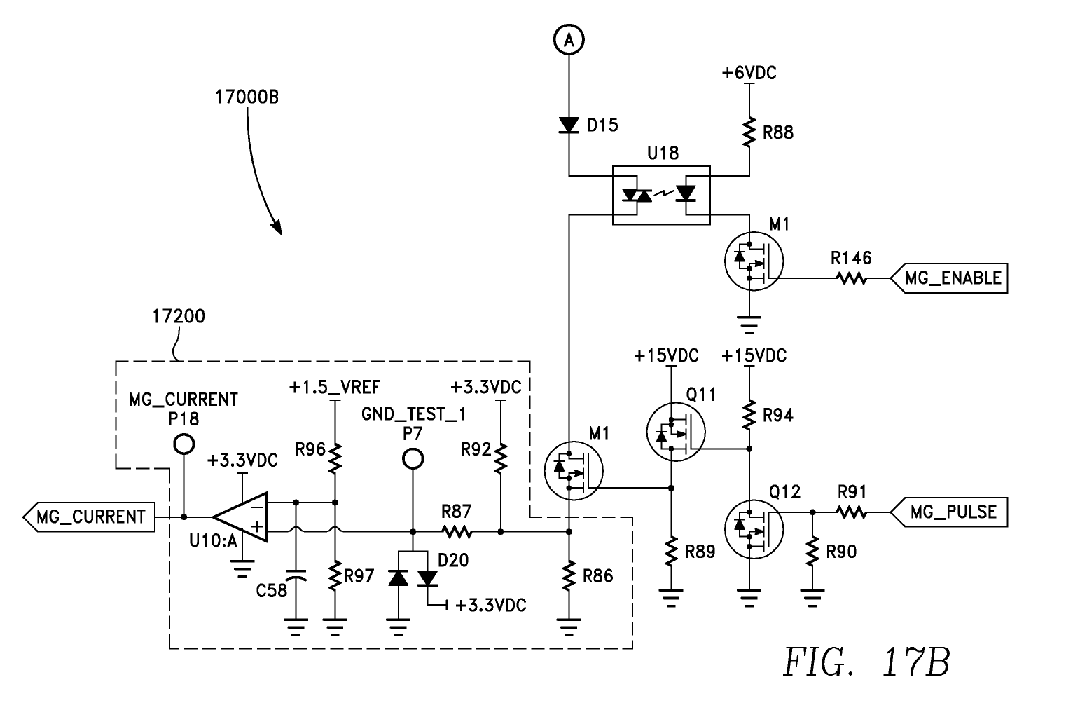

FIG. 17 is shows a simplified schematic of a single phase pulsed impedance circuit 17000 in accordance with one embodiment. In this embodiment, a optically coupled gating switch U18 is included to allow the disabling of the pulse control transistor M1. The MG_ENABLE signal can be used to open the optically coupled gating switch U18 if a current is sensed by the current sensing circuit 17200 when the pulse control transistor M1 open, indicating a short through the pulse control transistor M1.

Referring to FIG. 18, shown is a simplified schematic view of utility power supply equipment having a cable 100 to supply utility power to an electric vehicle (not shown) along with some associated circuitry. In the embodiment of FIG. 1, the cable 100 contains L1 and L2 and ground G lines. The cable 100 connects to utility power at one end 100u and to an electric vehicle (not shown) at the other end 100c. The electric vehicle (not show) could have an onboard charger, or the electric vehicle end 100c of the cable 100 could be connected to a separate, optionally free standing, charger (not shown). The separate charger (not shown) would in turn be connected to the electric vehicle for charging onboard batteries, or other charge storage devices. In other embodiments not shown, a charger could be integrated into the cable 100.

The cable 100 contains current transformers 110 and 120. The current transformer 110 is connected to a GFI circuit 130 which is configured to detect a differential current in the lines L1 and L2 and indicate when a ground fault is detected. The pulsed impedance circuits disclosed herein may be utilized in the supply equipment to indicate a missing or otherwise inadequate ground fault. Contactor 140 may be open circuited in response to a detected ground fault to interrupt utility power from flowing on lines L1 and L2 to the vehicle (not shown). The supply equipment may have a system processor 500 (FIG. 19) associated therewith for controlling or assisting with the functions of the circuitry of the supply equipment.

It is worthy to note that any reference to “one embodiment” or “an embodiment” means that a particular feature, structure, or characteristic described in connection with the embodiment may be included in an embodiment, if desired. The appearances of the phrase “in one embodiment” in various places in the specification are not necessarily all referring to the same embodiment.

The illustrations and examples provided herein are for explanatory purposes and are not intended to limit the scope of the appended claims. This disclosure is to be considered an exemplification of the principles of the invention and is not intended to limit the spirit and scope of the invention and/or claims of the embodiment illustrated.

Those skilled in the art will make modifications to the invention for particular applications of the invention.

The discussion included in this patent is intended to serve as a basic description. The reader should be aware that the specific discussion may not explicitly describe all embodiments possible and alternatives are implicit. Also, this discussion may not fully explain the generic nature of the invention and may not explicitly show how each feature or element can actually be representative or equivalent elements. Again, these are implicitly included in this disclosure. Where the invention is described in device-oriented terminology, each element of the device implicitly performs a function. It should also be understood that a variety of changes may be made without departing from the essence of the invention. Such changes are also implicitly included in the description. These changes still fall within the scope of this invention.

Further, each of the various elements of the invention and claims may also be achieved in a variety of manners. This disclosure should be understood to encompass each such variation, be it a variation of any apparatus embodiment, a method embodiment, or even merely a variation of any element of these. Particularly, it should be understood that as the disclosure relates to elements of the invention, the words for each element may be expressed by equivalent apparatus terms even if only the function or result is the same. Such equivalent, broader, or even more generic terms should be considered to be encompassed in the description of each element or action. Such terms can be substituted where desired to make explicit the implicitly broad coverage to which this invention is entitled. It should be understood that all actions may be expressed as a means for taking that action or as an element which causes that action. Similarly, each physical element disclosed should be understood to encompass a disclosure of the action which that physical element facilitates. Such changes and alternative terms are to be understood to be explicitly included in the description.

Having described this invention in connection with a number of embodiments, modification will now certainly suggest itself to those skilled in the art. The example embodiments herein are not intended to be limiting, various configurations and combinations of features are possible. As such, the invention is not limited to the disclosed embodiments, except as required by the appended claims.

1. A method to detect a ground fault, the method comprising:
a) applying a pulsed test impedance;
b) detecting a utility power voltage with and without the pulsed test impedance applied;
c) detecting a test current through the pulsed test impedance to ground; and
d) determining whether a ground fault exists based on the detected test current and the detected utility power voltage with and without the pulsed test impedance applied.

2. The method of claim 1 comprising detecting the utility power voltage before the application of the test impedance.

3. The method of claim 1 comprising detecting the utility power voltage after applying of the pulsed test impedance.

4. The method of claim 1, wherein applying the pulsed test impedance comprises pulsing with a limited in duration and frequency so that a ground fault interrupt circuit does not indicate a short circuit to ground.

5. The method of claim 4, wherein applying the pulsed test impedance comprises pulsing the test impedance pulse with a duration such that the test impedance will not cause a ground fault interrupt.

6. The method of claim 1, wherein applying the pulsed test impedance comprises pulsing the test impedance with a frequency such that the test impedance will not cause a ground fault interrupt.

7. The method of claim 1, wherein applying the test pulsed impedance comprises pulsing the test impedance with a frequency such that the test impedance will not cause a ground fault interrupt.

8. The method of claim 1, applying the pulsed test impedance comprises applying a single pulse.

9. A method to detect a ground fault, the method comprising:
a) sensing a utility line test voltage without applying a test impedance;
b) applying a test impedance pulse;
c) sensing the utility line voltage while applying the test impedance pulse;
d) sensing a current through the test impedance while applying the test impedance pulse;
e) determining an impedance through the test impedance to a ground using the sensed utility line test voltage without the test impedance pulse applied and the sensed the utility line voltage while the test impedance pulse is applied; and
f) causing a ground fault when the test impedance to ground impedance exceeds a threshold value.

10. The method of claim 9, wherein applying the test impedance pulse comprises applying the test impedance pulse with a duration such that the test impedance will not cause a ground fault interrupt.

11. The method of claim 10, wherein applying the test impedance pulse comprises pulsing the test impedance pulse with a frequency such that the test impedance will not cause a ground fault interrupt.

12. The method of claim 9, wherein applying the test impedance pulse comprises pulsing the test impedance pulse with a frequency such that the test impedance will not cause a ground fault interrupt.

13. The method of claim 9, wherein applying the pulsed test impedance comprises pulsing with a limited in duration and frequency so that a ground fault interrupt circuit does not indicate a short circuit to ground.

14. A ground fault detection circuit, the circuit comprising:
a) a line voltage sense circuit connected to a utility power input;
b) a pulse control transistor connected via a current generating resistor to a utility power input; and
c) a current sense circuit comprising a current sense resistor connected to the utility power via the pulse control transistor.

15. The circuit of claim 14, wherein the pulse control transistor comprises a gate, and further comprising a gate driver circuit connected to the pulse control transistor, the gate driver circuit being connected to receive a pulse control signal.

16. The circuit of claim 15 further comprising a gain amplifier connected to an output of the line voltage sense circuit.

17. The circuit of claim 14 further comprising a gain amplifier connected to an output of the line voltage sense circuit.

18. The circuit of claim 14 further comprising a second utility power input connected to the line voltage sense circuit, and wherein the second utility power input is connected to the pulse control transistor via the current generating circuit.

19.-27. (canceled)
